(19) United States
(12) Patent Application Publication
(10) Pub. No.: US 2025/0311083 A1
(43) Pub. Date: Oct. 2, 2025

(54) COOLER DETECTION AND ATTACH CHARACTERIZATION IN SYSTEM

(71) Applicant: NVIDIA Corp., Santa Clara, CA (US)

(72) Inventors: Benjamin Goska, Portland, OR (US); Ryan Kelsey Albright, Beaverton, OR (US); William Andrew Mecham, Elk Grove, CA (US); Aaron Richard Carkin, Hillsboro, OR (US); William Ryan Weese, Portland, OR (US); Jordan Levy, Portland, OR (US); Michael Scott Thompson, Wilsonville, OR (US)

(73) Assignee: NVIDIA Corp., Santa Clara, CA (US)

(21) Appl. No.: 18/622,345

(22) Filed: Mar. 29, 2024

(51) Int. Cl. H05K 1/02

(52) U.S. Cl. CPC H05K 1/0203

(57) ABSTRACT

An apparatus including an integrated circuit and logic to control power consumption of the integrated circuit based on a determination of thermal contact between a cooling element and the integrated circuit. A device including an integrated circuit, a cooling element, and logic to control heat generation by the integrated circuit based on a determination of thermal resistance between the integrated circuit and the cooling element.

### BACKGROUND

Electrical components that generate substantial heat during operation include graphics processing units (GPUs) and central processing units (CPUs). These components often consume a significant amount of power, even in idle states (low or no work loads), and typically utilize heat dissipation elements (e.g., heat sinks, cold plates-aka coolers) to manage the heat they generate. Such devices may incur thermal damage and/or performance issues if powered without a properly installed cooler.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts an apparatus including an integrated circuit and a cooler in one embodiment.

FIG. 2A depicts an apparatus including an integrated circuit and a cooler in another embodiment.

FIG. 2B depicts an apparatus including an integrated circuit and a cooler in yet another embodiment.

FIG. 2C depicts an apparatus including an integrated circuit and a cooler in yet another embodiment.

FIG. 3 depicts an embodiment of a data center comprising an integrated circuit thermal monitoring center.

FIG. 4 depicts exemplary logic to determine thermal resistance.

FIG. 5 depicts an exemplary data center 500 in accordance with at least one embodiment.

### DETAILED DESCRIPTION

Disclosed herein are mechanisms to verify proper cool installation and to implement power gating in circumstances in which a cooler is not present or not properly installed. These mechanisms may be applied to help ensure proper cooler attachment to electrical devices before enabling the application of power to those devices.

In one embodiment, a safe power mode is enabled for devices. Devices may operate in this mode even when a cooler is not present or is not properly installed. In the safe power mode, internal power gating is activated for the bulk of internal components in the device, or for the internal components that generate most of the heat, so that the integrated circuit is not damaged by operational heat even absent proper installation of a cooler.

The proper operation and longevity of heat-generating electrical devices depends on proper attachment and configuration of cooler elements, and the disclosed mechanisms help prevent malfunctions, damage, and down time of said devices and the larger systems that utilize them.

The disclosed mechanisms may have particular utility with high power-consuming integrated circuits such as GPUs and CPUs in deployments in which inspection and monitoring of such devices is difficult and/or costly. Datacenter installations are one example of such deployments.

The disclosed mechanisms may also be utilized in manufacturing and/or testing environments to detect and prevent the activation of damaging power modes on devices that lack a properly installed cooler.

In one aspect, an apparatus includes an integrated circuit and logic to control power consumption of the integrated circuit based on a determination of thermal contact between a cooling element and the integrated circuit. “Thermal contact” should be understood to include one or both of physical contact between between the cooler and the circuit, and an indication of thermal resistance between those components. For example, the determination of thermal contact may be based on detecting the existence of, or extent of, physical contact between the cooler and the circuit, and/or based on an amount of thermal resistance determined to exist between the cooling element and the integrated circuit.

The thermal contact detector may be a component of the integrated circuit or external to it, for example on a substrate or as a component of the cooler.

The logic to control power consumption may comprise a thermal contact sensor and power gates for the integrated circuit responsive to the thermal contact sensor. The logic to control power consumption may initiate a safe power mode of the integrated circuit in response to lack of engagement or insufficient thermal contact/engagement between the cooling element and the integrated circuit. The safe power mode may initiated by power gating a majority of internal components of the integrated circuit, and/or by by power gating particular high-thermal load components of the integrated circuit.

In some implementations, the integrated circuit includes the power gates whereby power consumption is controlled. The other implementations the power gates may be external to the integrated circuit.

In another aspect, contact elements may be utilized, with a sensor coupled to the contact element, and the power consumption level of the integrated circuit may be controlled based on engagement of the contact elements with a cooling element. For implementations in which the integrated circuit is mounted on a substrate, the contact element may extend from the substrate, externally from the integrated circuit. In implementations in which the integrated circuit is mounted in a socket, the socket may be formed with the contact element(s).

In yet another aspect, one or both of the integrated circuit or the cooler may include the sensor(s) that detects and/or determines the engagement of the contact elements with the cooler. Alternatively, the sensor may mounted on a substrate external from the integrated circuit and/or the cooler.

One embodiment of a device includes an integrated circuit, a cooling element, and logic to control heat generation by the integrated circuit based on a determination of thermal resistance between the integrated circuit and the cooling element. The determination of thermal resistance may utilize one or more of a thermal mass of the integrated circuit, a thermal mass of the cooling element, a rate of heat transfer between the integrated circuit and the cooling element, and a rate of heat transfer between the cooling element and an environment.

Other technical features may be readily apparent to one skilled in the art from the following figures, descriptions, and claims.

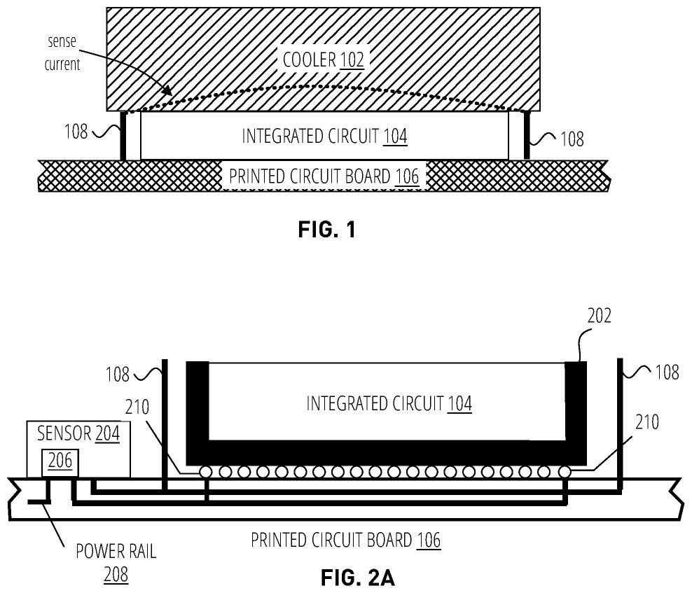

FIG. 1 depicts an apparatus in one embodiment. A cooler 102 such as a heat sink or cooling plate is disposed in thermal contact with an integrated circuit 104 such as a central processing unit (CPU), a graphics processing unit (GPU), or system-on-a-chip (SoC). The integrated circuit 104 is mounted on a printed circuit board 106, e.g., directly via soldering or using a socket mount 202. One or more sensing couplings 108 are utilized to enable a sense current through the cooler 102 on condition that the cooler 102 is located and oriented in a manner that provides sufficient thermal contact with the integrated circuit 104. The following figures depict exemplary arrangements of logic to control power consumption of and/or heat dissipation from the integrated circuit 104 according to the extent of said thermal contact.

The sensing coupling 108 may for example be implemented as a “pogo” spring or gold-plated leaf spring contact. These and other techniques are familiar in the art.

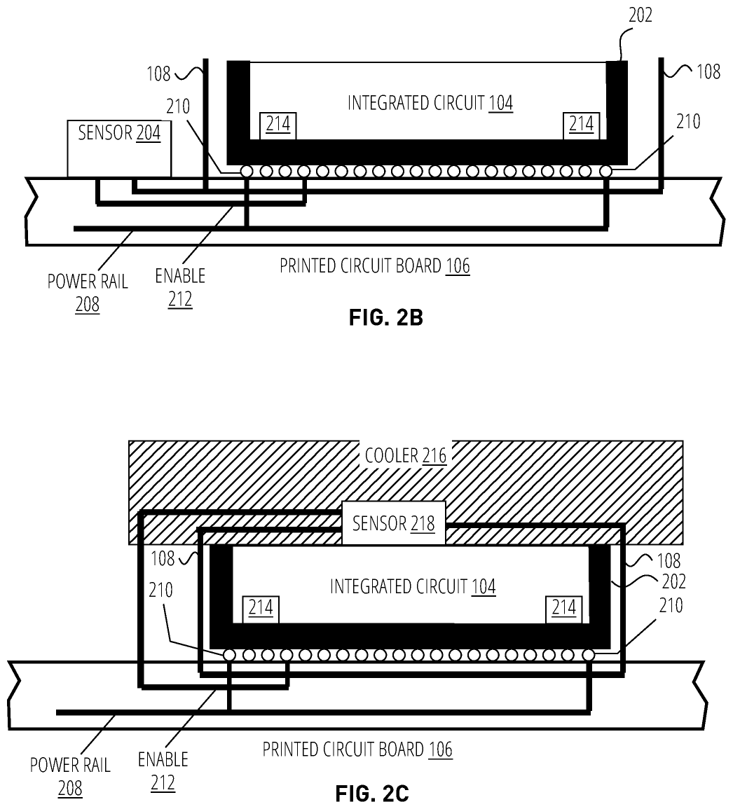

FIG. 2A depicts an embodiment of an integrated circuit 104 disposed in a socket mount 202 and utilizing an external sensor 204 for power and/or heat control based on thermal contact with a cooler 102. The sensor 204 controls one or more power gates 206 on a power rail 208 to the power pins 210 of the integrated circuit 104. The sensor 204 is also configured to detect the sense current (or related effects, such as electrical resistance or electrical potential between the sensing couplings 108) between the sensing couplings 108. The sensor 204 enables power through the power gates 206 to the power pins 210 of the integrated circuit 104 on condition that the sense current (or related effect) is indicative of adequate thermal contact between the cooler 102 and the integrated circuit 104.

In the depicted embodiment the sensing couplings 108 are implemented external to the integrated circuit 104 and/or the socket mount 202, e.g., spring pins or wire bonds. In other embodiments the sensing couplings 108 may be implemented as modifications to the socket mount 202 (e.g., contact elements along a surface of the socket mount 202 that engages with the cooler 102), or as contact elements along a surface of the integrated circuit 104 that engages with the cooler 102.

FIG. 2B depicts an embodiment in which the sensor 204 does not power gate the power rail 208 to the power pins 210 of the integrated circuit 104, but instead detects the thermal contact between cooler 102 and the integrated circuit 104 and generates an enable 212 signal to the integrated circuit 104. The enable 212 signal operates one or more power gates 214 of the integrated circuit 104 that determine the power mode of the integrated circuit 104 (e.g., a safe, low power mode vs a full-power mode). For example the integrated circuit 104 may power-up in a safe mode and transition to a full-power mode upon receipt of the enable 212 signal indicative of sufficient thermal contact between the integrated circuit 104 and a cooler 102.

FIG. 2C depicts an embodiment wherein the cooler 216 comprises a thermal contact sensor 218. In addition to detecting physical contact between the integrated circuit 104 and the cooler 216, the sensor 218 may also determine a metric of thermal resistance between those elements. For example, the sensor 218 may measure a temperature of the integrated circuit 104 utilizing one or more thermocouples, and may receive an indication of the power consumption of the integrated circuit 104 from the printed circuit board 106 or the integrated circuit 104 itself. From these readings the sensor 218 may estimate the thermal resistance between the cooler 216 and the integrated circuit 104 and may control the power mode of the integrated circuit 104 on that basis, e.g., but disabling or limiting use of the certain high-heat generating components of the integrated circuit 104 via operation of the power gates 214.

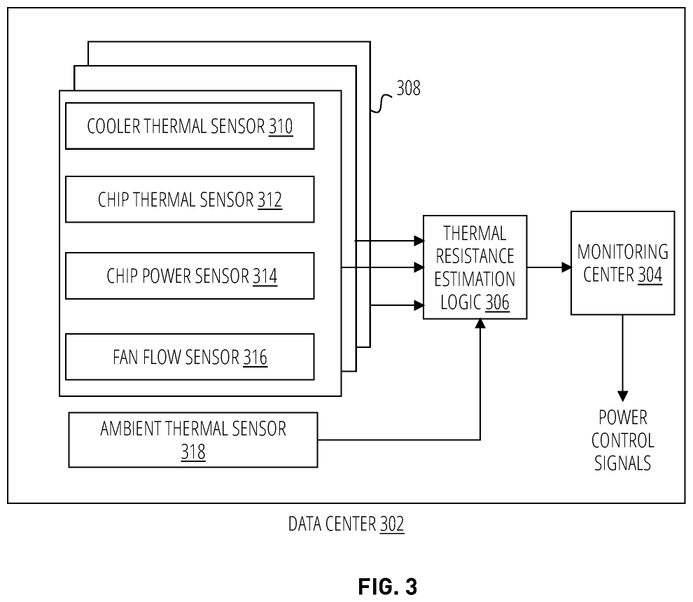

FIG. 3 depicts an embodiment of a data center 302 comprising an integrated circuit thermal monitoring center 304. For each of a plurality of integrated circuits utilized in the data center 302, thermal resistance estimation logic 306 determines an estimate of thermal resistance that is utilized by the monitoring center 304 to control the power/heating of the integrated circuits. The thermal resistance estimation logic 306 receives measurements from a plurality of server systems 308 that comprise the integrated circuits. A given server system 308 may comprise one or more of a cooler thermal sensor 310, a chip thermal sensor 312, a chip power sensor 314, and a fan flow sensor 316. Herein, ‘chip’ refers to an integrated circuit or die. The thermal resistance estimation logic 306 may also utilize readings from an ambient thermal sensor 318 (e.g., air temperature in the data center 302).

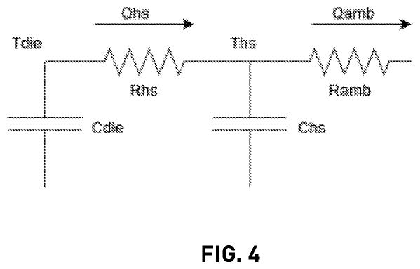

FIG. 4 depicts exemplary logic to determine thermal resistance, where various system parameters are modeled electronically. Measurement of thermal resistance may be beneficial to determine not only whether thermal contact exists between a cooler 102 and an integrated circuit 104, but also an extent/degree of said thermal contact. This may be useful for example in situations where the cooler 102 is installed on the integrated circuit 104, but installed incorrectly, providing insufficient thermal contact for cooling the integrated circuit 104. chip power sensor 314.

In on example of a thermal model the parameters are:
Qₕₛ—Thermal energy generated by the integrated circuit.
Q_{amb}—Energy transferred to air/water by the cooler.
T_{die}—Temperature at the integrated circuit (e.g., determined by thermal sensors on the die)
Tₕₛ—Temperature at the cooler (e.g., determined by thermal sensors on the cooler).
Rₕₛ—Thermal resistance between the integrated circuit and the cooler.
R_{amb}—Cooler thermal resistance to ground/ambient
C_{die}—Thermal mass of the integrated circuit
Cₕₛ—Thermal mass of the cooler

At steady state operation the thermal resistance Rₕₛ of the model in FIG. 4 may be calculated as:

$${R}_{hs} = \frac{{T}_{die} - {T}_{hs}}{Q}$$

where Q is determined by:

$$Q = {C}_{hs} Δ T$$

The parameter Q may be understood to represent an amount of heat transfer over an interval, and Rₕₛ is determined based on this bulk transfer and a thermal difference at some measurement instant. When operating the integrated circuit outside of steady state, measurements of the relevant parameters from the model in FIG. 4 may be taken over time and fit to the thermal model. The value of Q may be adjusted to account for the energy transferred into the thermal masses when such can be determined. The energy consumed by the integrated circuit between measurement points may be estimated by integration or summation over the interval.

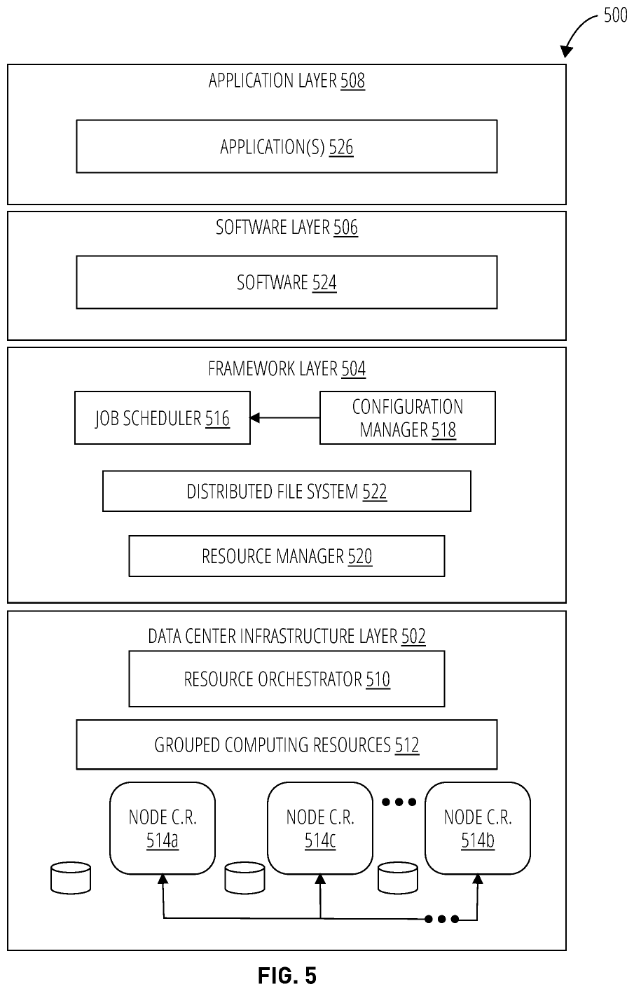

FIG. 5 depicts an exemplary data center 500, in accordance with at least one embodiment. In at least one embodiment, data center 500 includes, without limitation, a data center infrastructure layer 502, a framework layer 504, a software layer 506, and an application layer 508.

Embodiments of the disclosed mechanisms such as the monitoring center 304 to track and control power and/or heating of integrated circuits utilized in server system 308 may be implemented for example in the data center infrastructure layer 502.

In at least one embodiment, as depicted in FIG. 5, data center infrastructure layer 502 may include a resource orchestrator 510, grouped computing resources 512, and node computing resources (node C.R.s) 514a-514b, where “N” represents any whole, positive integer. In at least one embodiment, node computing resources may include, but are not limited to, any number of central processing units (CPUs) or other processors (including accelerators, field programmable gate arrays (FPGAs), graphics processors, etc.), memory devices (e.g., dynamic read-only memory), storage devices (e.g., solid state or disk drives), network input/output (NW I/O) devices, network switches, virtual machines (VMs), power modules, and cooling modules, etc. In at least one embodiment, one or more node computing resources from among node computing resources 514a-514b may be a server having one or more of the above-mentioned computing resources.

In at least one embodiment, grouped computing resources 512 may include separate groupings of node computing resources housed within one or more racks (not shown), or many racks housed in data centers at various geographical locations (also not shown). Separate groupings of node computing resources within grouped computing resources 512 may include grouped compute network, memory, or storage resources that may be configured or allocated to support one or more workloads. In at least one embodiment, several node computing resources including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 510 may configure or otherwise control one or more node computing resources 514a-514b and/or grouped computing resources 512. In at least one embodiment, resource orchestrator 510 may include a software design infrastructure (“SDI”) management entity for data center 500. In at least one embodiment, resource orchestrator 510 may include hardware, software, or some combination thereof.

In at least one embodiment, as depicted in FIG. 5, framework layer 504 includes, without limitation, a job scheduler 516, a configuration manager 518, a resource manager 520, and a distributed file system 522. In at least one embodiment, framework layer 504 may include a framework to support software 524 of software layer 506 and/or one or more application(s) 526 of application layer 220. In at least one embodiment, software 524 or application(s) 526 may respectively include web-based service software or applications, such as those provided by Amazon Web Services, Google Cloud, and Microsoft Azure. In at least one embodiment, framework layer 504 may be, but is not limited to, a type of free and open-source software web application framework such as Apache SPARK™ (hereinafter “Spark) that may utilize a distributed file system 522 for large-scale data processing (e.g., “big data”). In at least one embodiment, job scheduler 516 may include a Spark driver to facilitate scheduling of workloads supported by various layers of data center 500. In at least one embodiment, configuration manager 518 may be capable of configuring different layers such as software layer 506 and framework layer 504, including Spark and distributed file system 522 for supporting large-scale data processing. In at least one embodiment, resource manager 520 may be capable of managing clustered or grouped computing resources mapped to or allocated for support of distributed file system 522 and job scheduler 516. In at least one embodiment, clustered or grouped computing resources may include grouped computing resources 512 at data center infrastructure layer 502. In at least one embodiment, resource manager 520 may coordinate with resource orchestrator 510 to manage these mapped or allocated computing resources.

In at least one embodiment, software 524 included in software layer 506 may include software used by at least portions of node computing resources 514a-514b, grouped computing resources 512, and/or distributed file system 522 of framework layer 504. One or more types of software may include, but are not limited to, Internet web page search software, e-mail virus scan software, database software, and streaming video content software.

In at least one embodiment, application(s) 526 included in application layer 508 may include one or more types of applications used by at least portions of node computing resources 514a-514b, grouped computing resources 512, and/or distributed file system 522 of framework layer 504. In at least one or more types of applications may include, without limitation, Compute Unified Device Architecture (CUDA) applications, 5G network applications, artificial intelligence applications, data center applications, and/or variations thereof.

In at least one embodiment, any of configuration manager 518, resource manager 520, and resource orchestrator 510 may implement any number and type of self-modifying actions based on any amount and type of data acquired in any technically feasible fashion. In at least one embodiment, self-modifying actions may relieve a data center operator of data center 500 from making possibly bad configuration decisions and possibly avoiding underutilized and/or poorly performing portions of a data center.

### LISTING OF DRAWING ELEMENTS

102 cooler
104 integrated circuit
106 printed circuit board
108 sensing coupling
202 socket mount
204 sensor
206 power gate
208 power rail
210 power pin
212 enable
214 power gate
216 cooler
218 sensor
302 data center
304 monitoring center
306 thermal resistance estimation logic
308 server system
310 cooler thermal sensor
312 chip thermal sensor
314 chip power sensor
316 fan flow sensor
318 ambient thermal sensor
500 data center
502 data center infrastructure layer
504 framework layer
506 software layer
508 application layer
510 resource orchestrator
512 grouped computing resources
514a node computing resource
514b node computing resource
514c node computing resource
516 job scheduler
518 configuration manager
520 resource manager
522 distributed file system
524 software
526 application(s)

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. An apparatus comprising:
an integrated circuit;
logic to control power consumption of the integrated circuit based on a determination of thermal contact between a cooling element and the integrated circuit.

2. The apparatus of claim 1, wherein the determination of thermal contact is based on an amount of thermal resistance between the cooling element and the integrated circuit.

3. The apparatus of claim 1, wherein the logic to control power consumption comprises:
a thermal contact sensor; and
power gates for the integrated circuit responsive to the thermal contact sensor.

4. The apparatus of claim 3, wherein the integrated circuit comprises the power gates.

5. The apparatus of claim 3, wherein the power gates are external to the integrated circuit.

6. The apparatus of claim 3, wherein the integrated circuit comprises the thermal contact detector.

7. The apparatus of claim 3, wherein the thermal contact detector is external to the integrated circuit.

8. The apparatus of claim 7, wherein the cooling element comprises the thermal contact detector.

9. The apparatus of claim 1, wherein the logic to control power consumption is configured to initiate a safe power mode of the integrated circuit in response to lack of engagement or insufficient thermal engagement between the cooling element and the integrated circuit.

10. The apparatus of claim 9, wherein the safe power mode is initiated by power gating a majority of internal components of the integrated circuit.

11. The apparatus of claim 9, wherein the safe power mode is initiated by power gating particular high-thermal load components of the integrated circuit.

12. A system comprising:
an integrated circuit;
a cooling element;
a contact element;
a sensor coupled to the contact element; and
logic to control a power consumption level of the integrated circuit based on engagement of the contact elements with the cooling element.

13. The system of claim 12, further comprising:
a substrate upon which the integrated circuit is mounted; and
the contact element extending from the substrate externally from the integrated circuit.

14. The system of claim 12, further comprising:
a socket in which the integrated circuit is mounted; and
the socket comprising the contact element.

15. The system of claim 12, wherein the integrated circuit comprises the sensor.

16. The system of claim 12, wherein the cooling element comprises the sensor.

17. The system of claim 12, further comprising:
a substrate upon which the integrated circuit is mounted; and
wherein the sensor is mounted on the substrate external from the integrated circuit.

18. A device comprising:
an integrated circuit;
a cooling element; and
logic to control heat generation by the integrated circuit based on a determination of thermal resistance between the integrated circuit and the cooling element.

19. The device of claim 18, wherein the determination of thermal resistance further utilizes a thermal mass of the integrated circuit.

20. The device of claim 18, wherein the determination of thermal resistance further utilizes a thermal mass of the cooling element.

21. The device of claim 18, wherein the determination of thermal resistance further utilizes a rate of heat transfer between the integrated circuit and the cooling element.

22. The device of claim 18, wherein the determination of thermal resistance further utilizes a rate of heat transfer between the cooling element and an environment.
